(19) United States
(12) Patent Application Publication
(10) Pub. No.: US 2026/0361129 A1
(43) Pub. Date: Nov. 12, 2026

(54) DIRECTIONAL CHI-GRID MID-INFRARED RECTENNA ENERGY-HARVESTING TILE

(71) Applicant: Jonathan Washburn, Austin, TX (US)

(72) Inventor: Jonathan Washburn, Austin, TX (US)

(21) Appl. No.: 19/672,212

(22) Filed: May 8, 2026

Related U.S. Application Data
(60) Provisional application No. 63/804,572, filed on May 12, 2025.

(51) Int. Cl. H02J 50/00; H02J 50/30; H10N 70/00; H10N 79/00

(52) U.S. Cl. CPC H02J 50/001; H02J 50/005; H02J 50/30; H10N 70/021; H10N 70/826; H10N 70/841; H10N 70/8833; H10N 79/00

(57) ABSTRACT

A directional mid-infrared rectenna energy-harvesting tile directly converts incident thermal radiation into DC electrical power. The tile includes a chi-grid array of unit cells disposed on a substrate. A plurality of the unit cells include phi-spiral antennas configured to receive mid-infrared thermal radiation and produce antenna-induced signals at feedpoints. Metal-insulator-metal tunnel diodes are electrically coupled at or near the feedpoints and rectify the antenna-induced signals by quantum tunneling. A DC collection network collects rectified outputs from the unit cells and provides DC electrical output derived from the incident thermal radiation. In preferred embodiments, the phi-spiral antennas are configured for broadband reception in an 8-14 micrometer atmospheric window, the unit-cell pitch is based on a target wavelength and phi, and a ground-plane-backed directional stack supports single-sided reception. The tile may be used in building, wearable, industrial, sensor-power, and thermal-management systems.

### CROSS-REFERENCE TO RELATED APPLICATIONS

This application claims the benefit of priority to U.S. Provisional Patent Application No. 63/804,572, filed May 12, 2025, the entirety of which is hereby incorporated by reference herein.

### BACKGROUND

The present disclosure relates to energy-harvesting devices and, more particularly, to directional mid-infrared rectenna tiles configured to directly convert incident thermal radiation into DC electrical power using phi-spiral antenna unit cells coupled to metal-insulator-metal tunnel diode rectifiers and arranged in a chi-grid array.

Every object above absolute zero emits thermal radiation. At ordinary room temperature, for example, objects near about 300 K emit substantial energy in the mid-infrared spectral region, with a peak wavelength near about 9.7 micrometers. A significant portion of this radiation lies within the atmospheric transparency window from about 8 micrometers to about 14 micrometers. This mid-infrared radiation is present in buildings, industrial environments, wearable environments, equipment enclosures, vehicles, and other settings, yet it remains difficult to harvest directly as electrical power.

Conventional energy-harvesting technologies do not adequately address this source of energy. Thermoelectric generators convert temperature gradients into electrical power using the Seebeck effect, but they require a thermal gradient and do not directly convert incident thermal radiation. Thermophotovoltaic systems convert photons into electrical energy using semiconductor junctions, but mid-infrared photons at ordinary ambient temperatures often have energies below the bandgaps of practical photovoltaic materials, and many thermophotovoltaic systems require elevated-temperature emitters to produce useful output. Pyroelectric harvesters require temporal temperature variation and can produce little or no output under steady thermal conditions. Radio-frequency energy harvesters generally require a nearby RF transmitter or strong electromagnetic source and typically provide limited ambient power density. Conventional rectenna systems have been demonstrated at microwave or millimeter-wave frequencies, but extension to mid-infrared wavelengths presents significant challenges in antenna geometry, diode response time, parasitic capacitance, impedance matching, nanoscale fabrication, and array-level electrical aggregation. A need therefore exists for a planar energy-harvesting structure capable of receiving incident mid-infrared thermal radiation, rectifying the received energy at frequencies corresponding to mid-infrared wavelengths, aggregating rectified outputs across many unit cells, and delivering useful DC electrical power without requiring sunlight, vibration, an RF transmitter, or a macroscopic temperature gradient. A further need exists for such a structure to be directional, scalable, compatible with tile or panel formats, and capable of being adapted to different thermal source temperatures and deployment environments while preserving a clear rectenna unit-cell architecture. The present disclosure addresses these needs with a directional chi-grid mid-infrared rectenna energy-harvesting tile. In preferred embodiments, the tile includes a plurality of chi-grid unit cells, each including a phi-spiral antenna configured for broadband mid-infrared reception and a metal-insulator-metal tunnel diode electrically coupled to the antenna at or near a feedpoint. Incident mid-infrared thermal radiation induces an alternating signal in the antenna, the tunnel diode rectifies the signal by quantum tunneling, and DC interconnects collect rectified outputs from the unit cells to provide electrical power. The disclosure further provides preferred antenna geometries, diode structures, directional layer stacks, array pitch relationships, electrical interconnection schemes, fabrication methods, validation approaches, and downstream systems that preserve the core rectenna architecture while supporting practical deployment.

### SUMMARY

The present disclosure provides a directional mid-infrared rectenna energy-harvesting tile configured to directly convert incident thermal radiation into DC electrical power. The tile includes a planar array of chi-grid unit cells. Each unit cell includes a phi-spiral antenna configured to receive mid-infrared thermal radiation and a metal-insulator-metal tunnel diode electrically coupled to the antenna to rectify an antenna-induced signal. Rectified outputs from a plurality of the unit cells are collected through DC interconnects and provided as electrical output.

In preferred embodiments, the phi-spiral antenna is configured for broadband reception in a mid-infrared spectral band. In some embodiments, the spectral band includes the atmospheric transparency window from about 8 micrometers to about 14 micrometers. In other embodiments, the spectral band is selected based on a thermal source temperature. A target wavelength may be determined from Wien's relationship, lambda_peak=2898/T, where lambda_peak is in micrometers and T is in kelvin. The phi-spiral antenna may be sized based on minimum and maximum wavelengths of the selected band, including by setting an inner radius based on lambda_min/(2 pi) and an outer radius based on lambda_max/(2 pi).

In preferred embodiments, each phi-spiral antenna has a golden-ratio spiral geometry. In one implementation, the antenna follows r(theta)=r0 * exp(theta/(phi * 2 pi)), where phi=(1+sqrt(5))/2. The phi-spiral geometry provides a self-similar broadband antenna structure suitable for receiving mid-infrared radiation over a target spectral band. Fabrication-toleranced phi-spiral variants, golden-ratio spiral variants, and logarithmic spiral variants having golden-ratio arm spacing may also be used while preserving the broadband mid-infrared rectenna function.

In preferred embodiments, the chi-grid unit cells are arranged at a pitch determined from a target thermal wavelength and phi. In one implementation, the pitch P satisfies P=lambda_target * phi. In other implementations, the pitch is approximately equal to lambda_target * phi, within a fabrication tolerance of lambda_target * phi, or otherwise selected relative to the target wavelength and phi to provide a desired fill factor, coupling behavior, and array response.

In preferred embodiments, the tile includes a directional stack. The directional stack may include a substrate, a ground plane, a dielectric spacer, an antenna metal layer, a metal-insulator-metal tunnel barrier region, a top electrode layer, DC busbars, and a passivation layer. The ground plane may be spaced from the antenna layer by about lambda_target/(4n), where n is a refractive index of the dielectric spacer. This spacing can cause radiation that would otherwise be lost to be reflected back toward the antenna layer, thereby supporting directional reception from one side of the tile.

The metal-insulator-metal tunnel diode may include a bottom electrode, a tunnel barrier, and a top electrode. In preferred embodiments, the tunnel barrier has a thickness from about 1 nm to about 5 nm and a barrier height from about 0.05 eV to about 0.5 eV. In one preferred embodiment, the diode includes a Ni/NiO/Au stack. Other MIM stacks may include Al/Al2O3/Pt, Cr/Cr2O3/Au, Ti/TiO2, HfO2-based barriers, or other asymmetric metal and insulator combinations that provide rectifying current-voltage behavior.

The rectified outputs from the unit cells may be collected in series strings, parallel groups, or series-parallel networks. In some embodiments, the tile includes DC busbars that connect a plurality of unit cells to an output terminal. In some embodiments, an optional power-conditioning circuit, such as a boost converter, switched-capacitor converter, phi-ratio switched-capacitor converter, regulator, storage capacitor, protection circuit, or load-matching circuit, conditions the collected DC power for a load.

In optional embodiments, the chi-grid array is partitioned into repeating supercells. In one embodiment, the supercell includes eight unit cells having an electrical feed ordering selected to provide mode-balanced collection. Such an arrangement may be associated with an eight-tick or roots-of-unity cancellation relationship used as a mathematical design scaffold for reducing common-mode or standing-wave bias across a portion of the array. This supercell arrangement is optional and is not required for the broadest rectenna tile architecture.

The tile may be fabricated on a flexible substrate, such as PET, PEN, or polyimide, or on a rigid substrate, such as glass, ceramic, silicon, or another support. Fabrication may include forming a ground plane, forming a dielectric spacer, patterning the phi-spiral antenna, forming a MIM tunnel barrier, depositing a top electrode, forming DC busbars, applying passivation, and testing electrical output. In some embodiments, the tile is fabricated using roll-to-roll processing, nanoimprint lithography, controlled oxidation, maskless lithography, sputtering, evaporation, atomic layer deposition, printing, or other thin-film and microfabrication processes.

The disclosure also provides methods of designing, making, and using the tile. A design method may include selecting a thermal source temperature, determining a target wavelength, selecting a spectral band, sizing the phi-spiral antenna, selecting the MIM stack, selecting the chi-grid pitch, selecting a directional stack spacing, selecting an electrical interconnection topology, and validating spectral response, diode rectification, and DC output. A method of use may include exposing the tile to a thermal radiation source, receiving mid-infrared radiation with the phi-spiral antennas, rectifying the antenna-induced signal with the MIM tunnel diodes, collecting DC current through the interconnects, and powering or charging an electrical load.

The tile may be used in downstream embodiments including building-integrated tiles, wall panels, wearable patches, industrial waste-heat panels, dual radiative-cooling and energy-harvesting panels, wireless sensor power modules, automotive sensor modules, spacecraft thermal harvesting panels, and agricultural monitoring devices. These downstream embodiments are examples of use and should not be understood as limiting the core rectenna tile architecture.

Formal verification may be used to support mathematical design consistency of selected relationships in the disclosed system. For example, formal verification may support relationships involving Wien peak placement in the mid-infrared range, atmospheric-window targeting, positive cell density, bounded efficiency factors, positive tile power under stated assumptions, phi identities, and optional eight-cell supercell mode relationships. Such formal verification supports the mathematical consistency of design rules and does not by itself establish physical conversion efficiency, manufacturing cost, durability, field performance, or commercial output unless separately supported by measurement, simulation, calculation, or specification.

Unless expressly identified as experimentally measured under stated conditions, numerical performance values in this disclosure, including efficiency, output power, power density, gain, beamwidth, aperture efficiency, cost, payback, yield, and durability, may represent measured values, simulated values, calculated values, design specifications, supplier specifications, or prophetic examples for corresponding embodiments.

### BRIEF DESCRIPTION OF THE DRAWINGS

FIG. 1 depicts an overall directional chi-grid mid-infrared rectenna energy-harvesting tile configured to receive incident mid-infrared thermal radiation and provide DC electrical output.

FIG. 2 depicts a chi-grid rectenna unit cell including a phi-spiral antenna, a feedpoint, a metal-insulator-metal tunnel diode, and a DC busbar connection.

FIG. 3 depicts phi-spiral antenna geometry, including inner radius, outer radius, golden-ratio arm spacing, wavelength-derived sizing relationships, and a target broadband reception band.

FIG. 4 depicts a metal-insulator-metal tunnel diode structure and rectification mechanism, including bottom and top electrodes, a tunnel barrier, an antenna feed conductor, a tunneling current path, and a rectified DC output path.

FIG. 5 depicts a directional rectenna tile layer stack including a substrate, ground plane, dielectric spacer, antenna metal layer, metal-insulator-metal barrier region, top electrode layer, DC busbar layer, passivation layer, and directional radiation paths.

FIG. 6 depicts a chi-grid array layout including array rows, array columns, unit-cell pitch, a pitch relationship based on a target wavelength and phi, and an optional eight-cell supercell arrangement.

FIG. 7 depicts an electrical collection architecture including rectified unit-cell outputs, series strings, parallel string groups, DC busbars, optional bypass capacitance, optional power conditioning, an output terminal, and a load interface.

FIG. 8 depicts a fabrication workflow for forming a chi-grid mid-infrared rectenna tile, including substrate preparation, ground-plane deposition, dielectric spacer formation, antenna patterning, tunnel-barrier formation, top-electrode deposition, busbar patterning, passivation, metrology, output testing, and completion of the tile.

FIG. 9 depicts a validation and deployment workflow including a thermal source, a rectenna tile under test, a calibrated infrared source, spectral response measurement, diode current-voltage measurement, DC output measurement, power-density calculation, downstream deployment embodiments, a validation report, and a fabrication design file.

### DETAILED DESCRIPTION

The disclosed technology provides a directional mid-infrared rectenna energy-harvesting tile that directly converts incident thermal radiation into DC electrical power. The core architecture includes a chi-grid array of rectenna unit cells, each unit cell including a phi-spiral antenna electrically coupled to a metal-insulator-metal tunnel diode at or near an antenna feedpoint. Incident mid-infrared thermal radiation induces an alternating electromagnetic signal in the phi-spiral antenna, the MIM tunnel diode rectifies the antenna-induced signal by quantum tunneling, and a DC collection network aggregates rectified outputs from a plurality of unit cells to provide electrical power. This core architecture does not require a thermoelectric temperature gradient, an intermediate thermal stage, a photovoltaic bandgap junction, mechanical vibration, or a radio-frequency transmitter.

As used herein, “mid-infrared radiation” includes electromagnetic radiation having wavelengths in a mid-infrared band, including but not limited to wavelengths from about 8 micrometers to about 14 micrometers. A “phi-spiral antenna” includes a spiral antenna geometry having golden-ratio spacing between spiral turns or arms. In preferred embodiments, the phi-spiral follows r(theta)=r0 * exp(theta/(phi * 2 pi)), where phi=(1+sqrt(5))/2. Fabrication-toleranced phi-spiral geometries, golden-ratio spiral geometries, and logarithmic spiral geometries having golden-ratio arm spacing may be used where they preserve broadband mid-infrared reception. A “chi-grid” refers to an array layout in which rectenna unit cells are arranged with pitch and feed organization selected for mid-infrared collection, array fill factor, and reduced destructive coupling. A “MIM tunnel diode” refers to a metal-insulator-metal junction configured to rectify high-frequency antenna-induced signals through quantum tunneling.

Unless expressly identified as experimentally measured under stated conditions, numerical values in this disclosure, including output power, power density, efficiency, gain, beamwidth, aperture efficiency, cost, yield, durability, and payback, may represent measured values, simulated values, calculated values, design specifications, supplier specifications, or prophetic examples. Formal verification described herein may support mathematical consistency of selected design relationships, including wavelength placement, phi-scaling, cell-density, efficiency-boundedness, and positive tile-power relationships, but does not by itself establish physical conversion efficiency, manufacturing cost, durability, or commercial performance unless separately supported.

For purposes of this disclosure, a chi-grid is not merely an arbitrary rectangular grid. A chi-grid refers to an array of rectenna unit cells in which unit-cell pitch, electrical feed organization, and DC collection topology are selected relative to a target mid-infrared wavelength so that the unit cells cooperate as a directional harvesting surface. In preferred embodiments, the pitch is based on lambda_target * phi. In other embodiments, the pitch is within a fabrication tolerance of that value or is otherwise selected to preserve fill factor and reduce destructive coupling between adjacent unit cells. A phi-spiral antenna includes a spiral antenna having golden-ratio arm spacing, including exact, scaled, rounded, or fabrication-toleranced implementations. A diode positioned at or near a feedpoint includes a diode positioned at the feedpoint, adjacent the feedpoint, or electrically coupled to the feedpoint so that an antenna-induced signal is delivered to the diode for rectification.

A DC collection network includes conductive structures that receive rectified outputs from a plurality of unit cells and combine those outputs into one or more tile-level outputs. The network may include row buses, column buses, local collection nodes, edge buses, series strings, parallel groups, series-parallel subarrays, vias, interlayer conductors, tile-edge connectors, or combinations thereof. A rectified output includes a DC voltage, DC current, charge packet, stored charge, or conditioned DC signal produced from a MIM tunnel diode after receiving an antenna-induced signal. Mode-balanced electrical collection refers to an electrical feed or collection arrangement in which outputs from a plurality of unit cells are ordered, phased, grouped, or routed to reduce common-mode pickup, standing-wave bias, row-column imbalance, or parasitic collection imbalance across a portion of the tile.

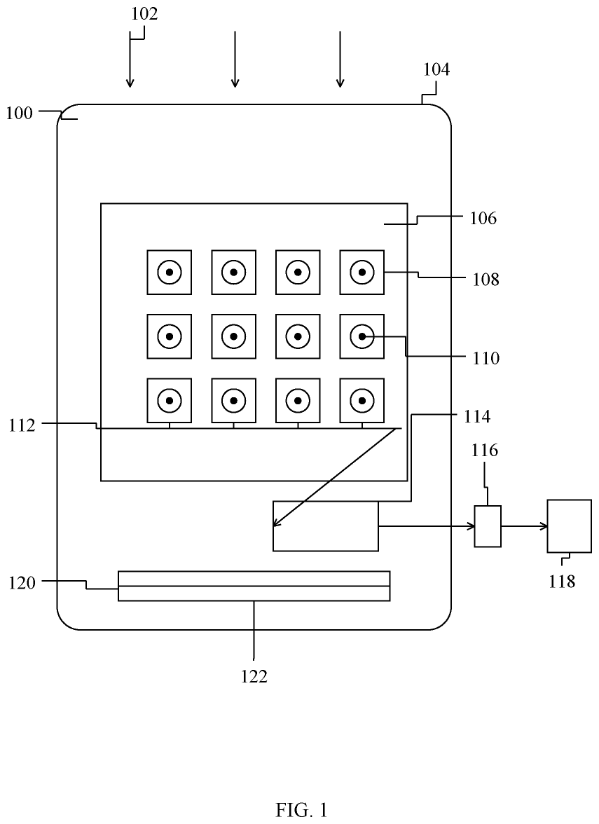

As shown in FIG. 1, an overall mid-infrared rectenna tile 100 receives incident mid-infrared thermal radiation 102 at a directional receiving surface 104. The tile 100 includes a chi-grid rectenna array 106 having a plurality of phi-spiral unit cells 108. Each phi-spiral unit cell 108 is coupled to one or more MIM tunnel diode rectifiers 110. Rectified outputs from the MIM tunnel diode rectifiers 110 are collected by a DC collection network 112. The DC collection network 112 may provide output through an optional power-conditioning circuit 114 to an output power terminal 116 and an electrical load 118. The tile may be supported by a substrate or support layer 120 and may include a ground-plane-backed directional stack 122. In operation, radiation incident on the receiving surface 104 is converted by the rectenna array 106 into DC electrical output without relying on macroscopic heat flow through the tile.

The thermal radiation source may be an ambient source, a building interior, a human body, industrial equipment, a heated surface, an enclosure, an engine component, a spacecraft surface, or another object or environment emitting mid-infrared radiation. In a design workflow, a source temperature T may be used to determine a target wavelength according to lambda_peak=2898/T, where lambda_peak is expressed in micrometers and T is expressed in kelvin. For a source near 300 K, lambda_peak is near about 9.7 micrometers, which lies within the 8-14 micrometer atmospheric transparency window. For higher-temperature sources, the target band may shift to shorter wavelengths, and the antenna dimensions, unit-cell pitch, and ground-plane spacing may be adjusted accordingly.

The thermal input may be characterized using Stefan-Boltzmann and Wien relationships. The total emitted power density of an ideal blackbody may be estimated by P_total=sigma * T\hat{ }4. At about 300 K, this relationship gives a total emitted power density of about 459W/m2. A preferred ambient operating band includes the 8 micrometer to 14 micrometer atmospheric window. In a calculated example, approximately 40 percent of the total 300 K blackbody spectrum lies in this window, corresponding to about 184 W/m2 of in-band thermal irradiance before view-factor, surface-emissivity, atmospheric-transmission, antenna-capture, matching, rectification, and collection losses. These values provide design context and should be treated according to their stated support level rather than as required output of every embodiment.

For ambient environments, the tile may be configured for a spectral band including about 8 micrometers to about 14 micrometers. For elevated-temperature industrial sources, the useful spectral band may shift toward shorter wavelengths, and the phi-spiral antenna dimensions, unit-cell pitch, MIM barrier material, and ground-plane spacing may be selected for that shifted band. Thus, an ambient building tile and an industrial heat-source tile may share the same rectenna architecture while using different wavelength-derived dimensions and material selections.

The antenna geometry, MIM tunnel barrier, unit-cell pitch, ground-plane spacing, and DC collection topology are co-designed for a selected thermal source or spectral band. The selected source temperature influences the target wavelength. The target wavelength influences the phi-spiral antenna dimensions, chi-grid pitch, and directional stack spacing. The diode barrier material, barrier thickness, junction area, and electrode asymmetry are selected so that the diode can rectify the antenna-induced signal at the relevant mid-infrared frequencies. The DC interconnection topology is selected so that low-voltage rectified outputs of many unit cells are aggregated into a usable tile-level output. This co-design distinguishes the disclosed tile from an arbitrary juxtaposition of a spiral antenna, a diode, and an array substrate.

The disclosed tile is not a mere aggregation of a spiral antenna, a rectifier diode, and an array substrate. At mid-infrared wavelengths, the antenna dimensions, diode tunneling response, diode capacitance, feedpoint impedance, unit-cell pitch, directional reflector spacing, and DC aggregation topology are mutually coupled. A change in target source temperature changes the target wavelength, which changes the antenna dimensions, unit-cell pitch, reflector spacing, and diode design constraints. The phi-spiral antenna, MIM tunnel diode, chi-grid pitch, directional stack, and DC collection network are therefore selected as a co-designed structure for direct mid-infrared thermal-radiation harvesting rather than as independently interchangeable components.

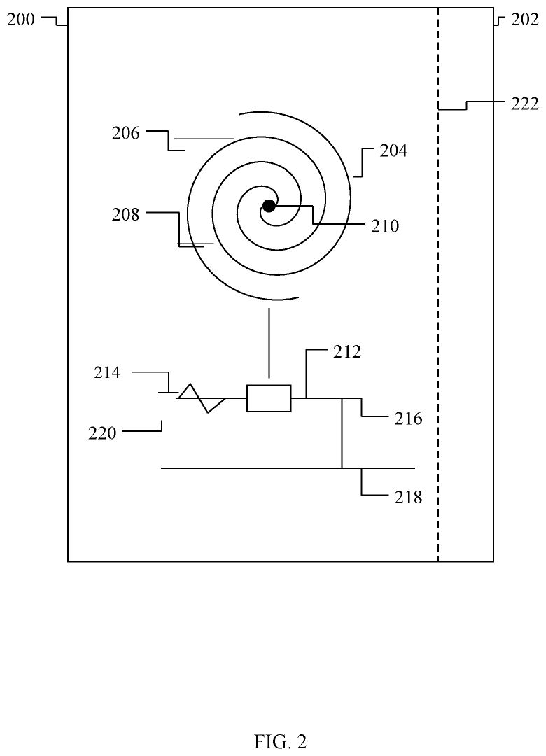

As shown in FIG. 2, a chi-grid unit cell 200 may include a unit-cell boundary 202, a phi-spiral antenna 204, a first spiral arm 206, a second spiral arm 208, an antenna feedpoint 210, a MIM tunnel diode 212, a bottom electrode connection 214, a top electrode connection 216, a DC busbar 218, an optional impedance-matching feature 220, and an adjacent unit-cell interface 222. The phi-spiral antenna 204 receives incident mid-infrared radiation and provides an antenna-induced signal at the feedpoint 210. The MIM tunnel diode 212 rectifies the antenna-induced signal and provides a rectified output to the DC busbar 218 through the electrode connections 214 and 216. The optional impedance-matching feature 220 may include a conductive stub, capacitive element, inductive feature, transmission-line section, or other matching structure configured to improve coupling between the antenna impedance and diode impedance.

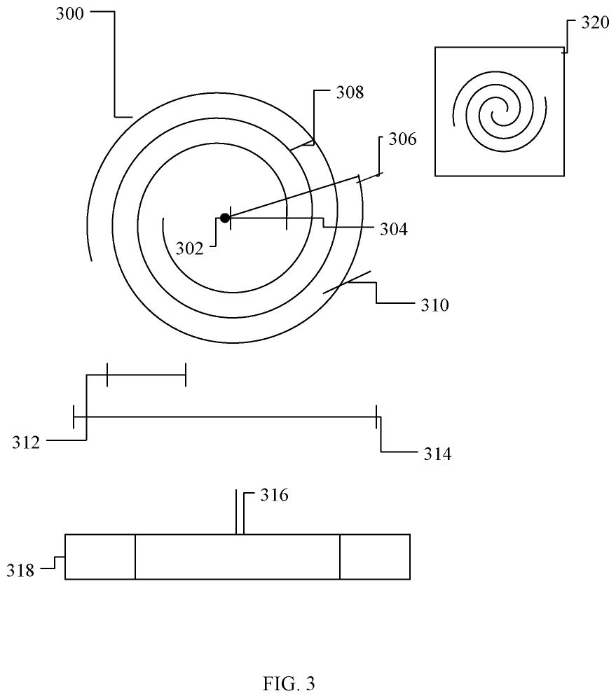

As shown in FIG. 3, a phi-spiral antenna geometry 300 includes a spiral center 302, an inner radius r_inner 304, an outer radius r_outer 306, golden-ratio arm spacing 308, a phi scaling interval 310, a lambda_min sizing relationship 312, a lambda_max sizing relationship 314, a target wavelength lambda_target 316, a broadband reception band 318, and a fabrication-toleranced spiral variant 320. In preferred embodiments, r_inner is selected based on lambda_min/(2 pi), and r_outer is selected based on lambda_max/(2 pi), where lambda_min and lambda_max define a target spectral band. For ambient mid-infrared harvesting, the target spectral band may include about 8 micrometers to about 14 micrometers. For industrial sources, the target spectral band may be shifted toward shorter wavelengths, such as about 5 micrometers to about 10 micrometers, depending on the source temperature. The phi-spiral geometry provides a self-similar broadband antenna structure and is a load-bearing feature of preferred embodiments, while toleranced variants may account for fabrication limitations.

In a preferred embodiment configured for the 8 micrometer to 14 micrometer atmospheric window, r_inner may be about 8/(2 pi), or about 1.27 micrometers, and r_outer may be about 14/(2 pi), or about 2.23 micrometers. A corresponding antenna diameter may be about 4.5 micrometers, subject to fabrication tolerances, conductor width, feedpoint geometry, dielectric environment, and desired spectral response. In other embodiments, the radii are scaled for a different spectral band selected from a thermal source temperature. These numerical examples provide preferred sizing relationships and are not required limitations of the broadest invention.

In some embodiments, the phi-spiral antenna is a two-arm, self-complementary spiral antenna. The input impedance may be approximately 94.5 ohms, corresponding to about one quarter of the free-space impedance, subject to conductor width, substrate dielectric properties, feedpoint geometry, and fabrication tolerances. The phi-spiral antenna may provide broadband reception across the selected band and may provide a directional response normal to the tile surface. In example embodiments, a single phi-spiral antenna may have a gain of about 4 dBi to about 6 dBi normal to the plane, and mutual coupling in a chi-grid array may narrow the received beam and increase gain relative to an isolated unit cell.

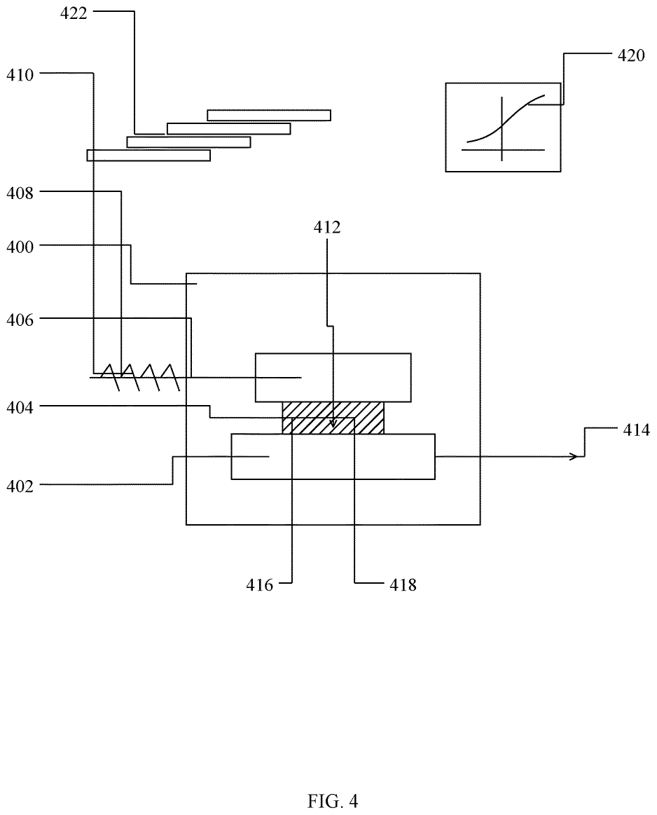

As shown in FIG. 4, a MIM tunnel diode 400 includes a bottom metal electrode 402, a tunnel barrier 404, and a top metal electrode 406. An antenna feed conductor 408 couples the diode 400 to the antenna feedpoint. An antenna-induced AC signal path 410 is provided from the antenna to the diode. A tunneling current path 412 passes through the tunnel barrier 404, and a rectified DC output path 414 provides rectified electrical output to the DC collection network. The tunnel barrier 404 may have a barrier thickness 416 and a barrier height region 418 selected for mid-infrared rectification. The diode may exhibit an asymmetric I-V response 420. Alternative MIM material stacks 422 may be used. In preferred embodiments, the tunnel barrier has a thickness from about 1 nm to about 5 nm, more preferably about 2 nm to about 3 nm, and a barrier height from about 0.05 eV to about 0.5 eV. Example stacks include Ni/NiO/Au, Al/Al2O3/Pt, Cr/Cr2O3/Au, Ti/TiO2, HfO2-based barriers, and asymmetric metal work-function combinations.

At a wavelength of about 10 micrometers, incident radiation has a frequency of about 30 THz and a period of about 33 fs. A MIM tunnel diode may provide a tunneling response time shorter than this period, including response times less than about 1 fs in preferred embodiments. At a wavelength of about 10 micrometers, photon energy is about 0.124 eV. A tunnel barrier, such as a NiO barrier having a barrier height of about 0.2 eV, may be selected so that the barrier energy is comparable to the photon energy associated with the target mid-infrared band. The rectifying behavior of the MIM tunnel diode may be characterized by I-V asymmetry, nonlinear conductance, responsivity, resistance-area product, junction capacitance, and tunneling response time. In preferred embodiments, the diode stack is selected so that the tunneling response time is shorter than the period of radiation in the target mid-infrared band, and the junction capacitance is sufficiently low to avoid suppressing rectification at the selected frequencies. The barrier thickness, barrier height, and electrode materials may be selected together with antenna impedance and feedpoint geometry so that the diode is matched to the mid-infrared antenna environment.

In preferred embodiments, the MIM tunnel diode has a nanoscale junction area defined by overlap between the bottom electrode and the top electrode. In one non-limiting example, the junction area is about 100 nm by about 100 nm. Other junction areas may be used depending on antenna impedance, diode resistance, junction capacitance, fabrication tolerance, and target spectral band. The diode may be characterized by I-V asymmetry, zero-bias curvature, resistance-area product, junction capacitance, responsivity, and tunneling response time. In one preferred implementation, a NiO MIM diode may have a responsivity on the order of about 5 V\hat{ }-1 to about 10 V\hat{ }-1, although responsivity values should be treated according to their support level as measured, simulated, calculated, specified, or prophetic. Fabrication quality control may include I-V sampling, short-circuit testing, open-circuit testing, oxide-thickness verification, junction-area inspection, sheet-resistance measurement, and statistical yield mapping across the tile.

In some embodiments, the antenna-to-diode interface is impedance matched. A MIM diode resistance may be in a range from about 100 ohms to about 1000 ohms, while a preferred phi-spiral antenna impedance may be about 94.5 ohms. An impedance-matching feature may therefore include an integrated LC stub, capacitive feature, inductive feature, transmission-line transformer, or other in-plane matching structure fabricated with the antenna and busbar layers. Matching may be selected to improve transfer of the antenna-induced signal to the MIM diode at the selected mid-infrared frequency band.

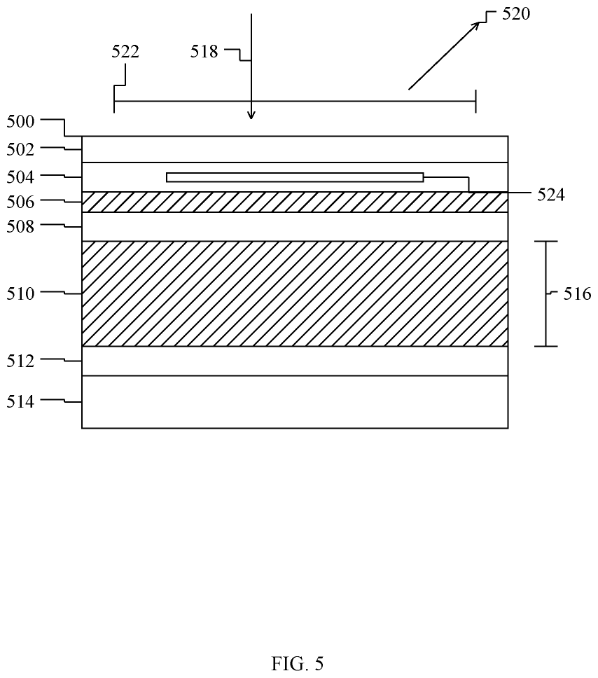

As shown in FIG. 5, a directional rectenna stack 500 may include a passivation layer 502, a top electrode layer 504, a MIM barrier region 506, an antenna metal layer 508, a dielectric spacer 510, a ground plane 512, a substrate 514, a quarter-wave spacing 516, an incident radiation path 518, a reflected radiation path 520, a directional aperture region 522, and a DC busbar layer 524. The ground plane 512 may be spaced from the antenna metal layer 508 by approximately lambda_target/(4n), where n is the refractive index of the dielectric spacer 510. This spacing may cause radiation passing through or around the antenna layer to be reflected back toward the antenna, supporting directional reception from one side of the tile. In some embodiments, the directional stack 500 is fabricated on a flexible polymer substrate, and in other embodiments the stack is fabricated on a rigid glass, ceramic, silicon, or high-temperature substrate.

In one preferred layer-stack example, the ground plane comprises aluminum having a thickness of about 200 nm, the dielectric spacer comprises SiO2 having a thickness selected near a quarter-wave optical spacing, the antenna metal comprises Ni or Au having a thickness of about 100 nm, the tunnel barrier comprises NiO having a thickness of about 2 nm to about 3 nm at the feedpoint region, the top electrode comprises Au having a thickness of about 50 nm, the DC busbar layer comprises Au having a thickness of about 200 nm, and the passivation layer comprises SiN having a thickness of about 100 nm. For a target wavelength of about 10 micrometers and a SiO2 refractive index of about 1.46, the quarter-wave spacer thickness may be about 10/(4 * 1.46), or about 1.7 micrometers. These layer materials and thicknesses are preferred examples and may be varied according to spectral band, fabrication method, substrate, temperature range, and durability requirements.

Although a ground-plane-backed quarter-wave stack is preferred for directional harvesting, other directional or field-enhancing structures may be used. A directional stack may include a metal ground plane, reflective backing, frequency-selective reflector, metamaterial reflector, dielectric mirror, resonant backing layer, or other structure selected to redirect or enhance mid-infrared fields at the antenna layer. In some embodiments, a non-directional or partially directional tile may omit the ground plane or use a thinner reflective structure where bidirectional reception, transparency, flexibility, cost, or fabrication simplicity is prioritized. These alternatives preserve fallback support while the preferred directional embodiment remains the ground-plane-backed stack.

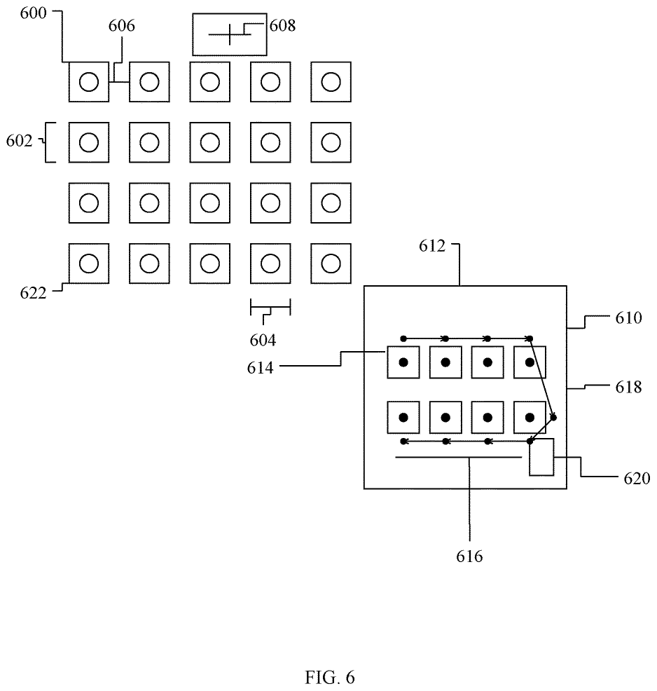

As shown in FIG. 6, a chi-grid array 600 includes an array row 602, an array column 604, a unit-cell pitch P 606, a lambda_target times phi pitch relationship 608, a repeating unit-cell region 610, an optional 8-cell supercell 612, a supercell feed ordering 614, a mode-balanced collection path 616, an adjacent-cell coupling region 618, an array edge connection 620, and a tile repeating region 622. In preferred embodiments, P=lambda_target * phi. In other embodiments, P is approximately equal to lambda_target * phi, within a fabrication tolerance of lambda_target * phi, or selected relative to lambda_target and phi to provide a desired balance between fill factor, spectral response, array coupling, and manufacturability. Tolerances may include plus or minus 1 percent, plus or minus 5 percent, plus or minus 10 percent, or another tolerance determined by fabrication and performance requirements.

In one preferred ambient embodiment, lambda_target is about 10 micrometers, and the unit-cell pitch P is about lambda_target * phi, or about 16.2 micrometers. This pitch corresponds to a cell density of about 1/P\hat{ }2, or about 3,810 cells/mm2. In a calculated example using an outer antenna radius of about 2.23 micrometers, the geometric fill factor of a circular antenna aperture within the unit-cell pitch may be about 60 percent, subject to conductor width, busbar routing, diode footprint, and layout rules. These values provide a preferred ambient-temperature design point and may be scaled for other target wavelengths or source temperatures.

The optional 8-cell supercell 612 may be used where mode-balanced electrical collection is desired. The supercell feed ordering 614 may arrange unit-cell outputs so that phase or mode contributions over the supercell tend toward cancellation or balance according to an eight-tick or roots-of-unity relationship. This optional supercell can reduce standing-wave bias, common-mode artifacts, or parasitic collection imbalance across portions of the array. The optional 8-cell supercell is a valuable fallback embodiment but is not required for every chi-grid rectenna tile.

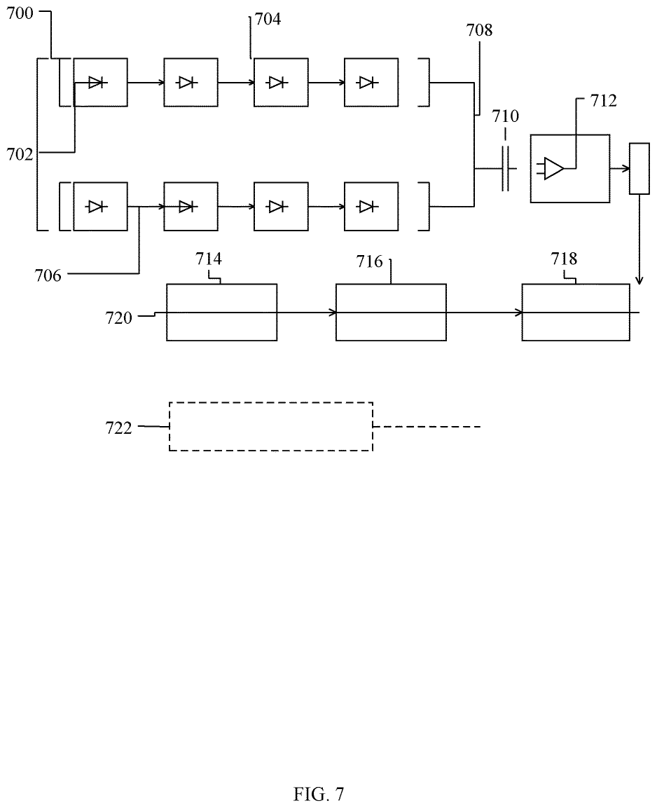

As shown in FIG. 7, an electrical collection architecture 700 may receive rectified unit-cell outputs 702. The outputs may be connected in a series string 704, a parallel string group 706, or another series-parallel topology. A DC busbar 708 collects output from the topology. A bypass capacitor 710 may reduce ripple or stabilize output. An optional boost converter 712 may raise the collected voltage to a regulated DC rail 714. The regulated DC rail 714 may be provided to an output terminal 716 and a load interface 718. A monitoring or protection circuit 720 may provide startup control, overvoltage protection, current limiting, load matching, or diagnostic output. A passive collection fallback path 722 may provide output without active power conditioning. In this way, the broadest tile does not require a boost converter, while preferred embodiments may include conditioning circuitry for practical loads.

The DC collection network may be physically routed as row buses, column buses, edge buses, local collection nodes, series strings, parallel groups, or series-parallel subarrays. In one implementation, rectified outputs from a plurality of unit cells are connected in series to increase voltage, and a plurality of series strings are connected in parallel to increase current. In another implementation, local groups of unit cells are aggregated at intermediate bus nodes before connection to a tile-edge output terminal. The DC collection network may include conductive busbars formed in the same metallization layer as one or more antenna conductors, in a separate busbar layer, or through vias or interlayer connections. The collection topology may be selected based on target output voltage, current, load impedance, tile area, diode yield, and acceptable routing loss.

In one non-limiting tile implementation, a standard tile may have dimensions of about 100 mm by about 100 mm. For a unit-cell pitch of about 16.2 micrometers, the tile may include on the order of 38 million unit cells. The unit cells may be grouped into series strings of about 1000 cells to build voltage, and a plurality of such strings, for example about 38,000 strings in a 100 mm by 100 mm tile implementation, may be connected in parallel to increase current. If each cell provides a rectified cell voltage on the order of millivolts under stated conditions, the series string may provide a tile-level open-circuit voltage in a range of about 2 V to about 5 V, subject to source temperature, irradiance, load, diode yield, interconnect loss, and support level of the reported value.

In some embodiments, output conditioning includes a switched-capacitor boost converter, a phi-ratio switched-capacitor converter, a regulator, bypass capacitance, or a storage element. In one preferred implementation, output conditioning may provide a regulated DC output such as about 3.3 V, with a thin-film ceramic bypass capacitance such as about 10 microfarads and output ripple less than about 50 mV peak-to-peak under stated operating conditions. These values are non-limiting design examples and may be varied according to tile area, load, and deployment environment.

The collection topology may include redundancy or fault tolerance. For example, a failed unit cell, failed diode, open circuit, or shorted string may be bypassed, isolated, or made electrically subordinate to neighboring parallel groups so that the tile continues to provide output. Bypass structures may include fusible links, printed jumpers, redundant bus traces, local isolation structures, passive bypass paths, or subarray-level routing. A tile may include one or more edge connectors or modular interconnects so that multiple tiles or subarrays can be connected to a panel-level bus. The collection network may therefore support a single unit cell, a subarray module, a full tile, or a multi-tile panel without changing the core rectenna mechanism.

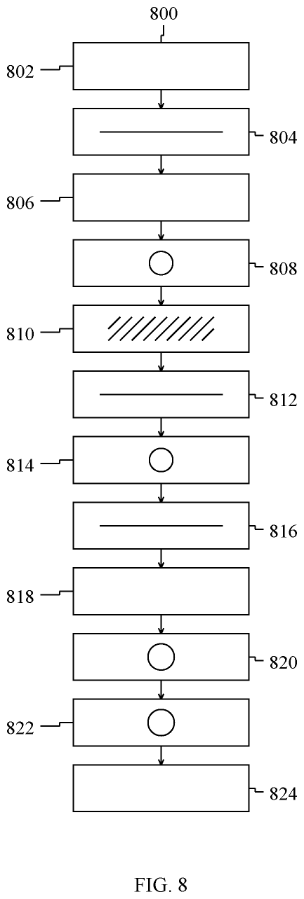

As shown in FIG. 8, a fabrication workflow 800 may include substrate preparation 802, ground-plane deposition 804, dielectric spacer formation 806, antenna patterning 808, MIM barrier formation 810, top electrode deposition 812, DC busbar patterning 814, passivation deposition 816, tile finishing 818, metrology inspection 820, electrical output testing 822, and completion of the rectenna tile 824. Antenna patterning may be performed by nanoimprint lithography, e-beam lithography, photolithography, laser writing, embossing, printing, or another process capable of forming mid-infrared antenna features. The MIM barrier may be formed by controlled oxidation, atomic layer deposition, sputtering, evaporation, chemical deposition, or another thin-film process. Roll-to-roll fabrication may be used in preferred manufacturing embodiments, but roll-to-roll fabrication is not required for the core rectenna tile.

The MIM tunnel barrier may be formed with controlled thickness and material composition to provide rectifying current-voltage behavior at mid-infrared frequencies. Barrier thickness may be controlled by oxidation time, oxygen partial pressure, atomic layer deposition cycle count, sputter conditions, evaporation conditions, plasma treatment, or post-deposition annealing. Junction area may be defined lithographically or by overlap between the bottom and top electrodes. In preferred embodiments, the diode stack is asymmetric, either through different electrode work functions, asymmetric barrier shape, different interface materials, or controlled oxide stoichiometry, so that the diode exhibits a nonlinear or asymmetric I-V response suitable for rectification.

A unit cell or subarray may be fabricated, tested, sold, integrated, or replaced independently of a complete tile. A subarray may include a plurality of chi-grid unit cells, local DC collection traces, one or more local test pads, and a subarray output node. Multiple subarrays may be combined to form a larger tile or panel. This modular approach permits fabrication yield management, subarray-level validation, panel repair, and different tile sizes while preserving the same phi-spiral antenna, MIM tunnel diode, and chi-grid collection architecture.

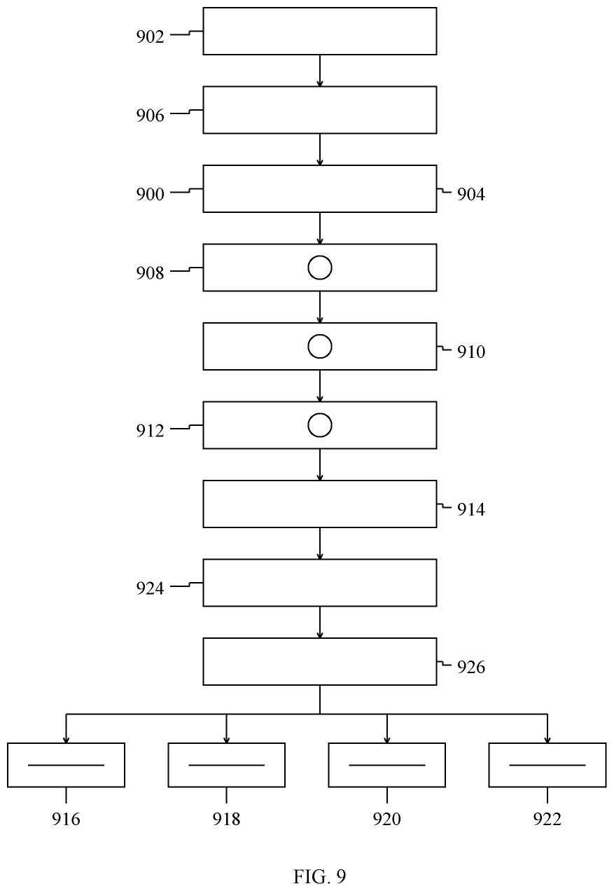

As shown in FIG. 9, a validation and deployment workflow 900 may include a thermal source 902, a rectenna tile under test 904, a calibrated IR source 906, a spectral response measurement 908, a diode I-V measurement 910, a DC output measurement 912, a power-density calculation 914, a building embodiment 916, a wearable embodiment 918, an industrial embodiment 920, a dual-mode cooling and harvesting embodiment 922, a validation report 924, and a fabrication design file 926. Validation may include measuring or simulating spectral absorption, impedance matching, diode responsivity, diode I-V asymmetry, rectified DC output, array continuity, output under load, output ripple, thermal cycling, environmental durability, and fabrication yield. The validation report 924 may identify whether a value is measured, simulated, calculated, specified, or prophetic. The fabrication design file 926 may define antenna geometry, pitch, layer stack, diode placement, interconnect topology, and tile dimensions for manufacturing.

Validation may include acceptance criteria such as a minimum rectified open-circuit voltage under a calibrated infrared source, a minimum loaded output power under stated irradiance, a measured diode I-V asymmetry above a selected threshold, a spectral response within a selected tolerance of the target band, continuity of a selected percentage of series strings, output ripple below a selected value after conditioning, and stable output over a selected thermal or mechanical cycling interval. A validation report may identify test conditions, source temperature, spectral band, irradiance, angle of incidence, view factor, load resistance, tile temperature, and whether each reported value is measured, simulated, calculated, specified, or prophetic.

In some embodiments, validation may include comparative testing or simulation against control structures. A control structure may include a non-phi spiral antenna, an antenna array having a non-phi-related pitch, a non-MIM rectifier, a non-directional stack, a different diode barrier thickness, a different junction area, or a different DC collection topology. Comparative validation may evaluate spectral capture, antenna-diode impedance behavior, diode I-V asymmetry, rectified DC output, directional response, output under load, array uniformity, or sensitivity to source temperature. Such comparisons may be used to evaluate the contribution of the co-designed phi-spiral antenna, MIM tunnel diode, chi-grid pitch, directional stack, and DC collection network.

The tile may be made by selecting an operating environment, determining a thermal source temperature, selecting a target wavelength or wavelength band, sizing the phi-spiral antenna, selecting a MIM diode stack, selecting a unit-cell pitch, selecting a directional stack spacing, selecting an electrical collection topology, and fabricating the resulting tile. The tile may then be exposed to a calibrated mid-infrared source or intended thermal source, and output may be measured under a defined load. Acceptance criteria may include a minimum rectified output voltage, minimum power density under stated irradiance, acceptable ripple after conditioning, minimum diode yield, acceptable sheet resistance, acceptable pitch fidelity, and acceptable spectral response across the target band.

In a building embodiment, a plurality of tiles may be mounted on a ceiling, wall, panel, or enclosure surface to harvest thermal radiation from a building interior. In a wearable embodiment, a flexible tile may be positioned on or near clothing, skin, or equipment to harvest body-emitted thermal radiation or thermal radiation exchanged between a body and an ambient environment. In an industrial embodiment, a tile may be positioned near a furnace, pipe, exhaust duct, kiln, engine, or heated surface. In a dual-mode embodiment, a panel may include a first surface configured for radiative cooling and a second surface including a chi-grid rectenna tile for harvesting radiation from below or from an interior region. These embodiments illustrate deployment options and do not limit the core rectenna architecture.

In one calculated or prophetic example, a tile is configured for an ambient room-temperature environment in which surrounding surfaces are at approximately 300 K. A target wavelength may be selected near the Wien peak of about 9.7 micrometers, and the antenna band may be selected to include the 8 micrometer to 14 micrometer atmospheric window. The phi-spiral antenna inner radius and outer radius may be selected based on the lower and upper wavelength limits of the band, and the unit-cell pitch may be selected based on P=lambda_target * phi or a fabrication-toleranced approximation thereof. Under a stated in-band irradiance and a stated overall conversion efficiency, the output power of the tile may be calculated from the incident in-band power, tile area, antenna capture efficiency, impedance-matching efficiency, diode rectification efficiency, and DC collection efficiency. Unless expressly identified as measured, such room-temperature output values should be understood as calculated, simulated, design-target, or prophetic values.

In a more specific calculated or prophetic ambient example, a 100 cm2 tile receives an in-band irradiance of about 184 W/m2 from 300 K surroundings. If antenna capture efficiency is about 0.70, impedance-matching efficiency is about 0.80, MIM diode AC-to-DC rectification efficiency is about 0.10, and DC collection efficiency is about 0.80, the overall conversion efficiency is about 0.045. Under those stated assumptions, output power may be calculated as 184 W/m2 times 0.01 m 2 times 0.045, or about 0.083 W. At an overall efficiency of about 1 percent, the same tile area would provide about 18.4 mW, and at an overall efficiency of about 5 percent it would provide about 92 mW. These values are calculated or prophetic unless separately identified as measured.

In another calculated or prophetic example, the tile is configured for an industrial heat source having a temperature above ambient temperature. The target wavelength may be shifted according to lambda_peak=2898/T, and the phi-spiral antenna dimensions, unit-cell pitch, and directional stack spacing may be adjusted for the shifted spectral band. For example, a heat source at about 500 K has a Wien peak at a shorter wavelength than a room-temperature source, and a corresponding tile may use smaller antenna dimensions and a different target pitch than a tile configured for a 300 K source. The MIM tunnel barrier material and barrier height may also be selected for improved rectification at the corresponding photon energies. Industrial embodiments may be fabricated on glass, ceramic, silicon, or other high-temperature substrates.

In a more specific calculated or prophetic industrial example, a source at about 500 K may have a total emitted power density of about 3544 W/m2, with a useful in-band portion estimated at about 1770 W/m2 for a selected 5 micrometer to 10 micrometer band. For a 100 cm2 tile and an assumed overall conversion efficiency of about 3 percent, output power may be calculated as about 1770 W/m2 times 0.01 m2 times 0.03, or about 531 mW. On an area-normalized basis, a corresponding panel may provide about 53 W/m2 under the stated assumptions.

In a wearable embodiment, the tile may be formed on a flexible substrate and configured to harvest mid-infrared radiation emitted by a wearer's body or exchanged between the wearer and the surrounding environment. The flexible substrate may include PET, PEN, polyimide, or another bendable support. The tile may include a passivation layer selected for skin proximity, moisture resistance, or mechanical durability. The output may power a low-power biosensor, wireless transmitter, memory device, or intermittent sensing circuit. This wearable embodiment remains subordinate to the core rectenna tile architecture and does not require that the broadest tile be flexible or body-worn.

In a calculated or prophetic wearable example, a flexible patch may have an active area of about 50 mm by about 50 mm and may be positioned to receive body-emitted mid-infrared radiation from skin at about 306 K. The in-band irradiance may be about 200 W/m2, and the net radiative exchange for a skin-to-ambient temperature difference of about 10 K may be estimated as about 61 W/m2. At an assumed overall conversion efficiency of about 2 percent, a 25 cm2 patch may provide about 3 mW under the stated assumptions, which may be sufficient for intermittent biosensing, memory, or wireless-transmitter operation.

In a building embodiment, a plurality of tiles may be mounted in or on ceiling panels, wall panels, equipment enclosures, ductwork, insulation layers, or other surfaces having a view factor to interior thermal sources. The tiles may face downward, outward, inward, or toward a selected thermal source depending on the geometry of the installation. A plurality of tile outputs may be connected to a power aggregation bus, energy storage device, DC-DC converter, lighting system, sensor network, or building automation system. Building embodiments may use rigid panels, flexible sheets, modular tiles, laminated surfaces, or replaceable cartridges. These embodiments should be understood as system-level uses of the rectenna tile rather than as limitations on the core rectenna cell and tile structure.

In a calculated or prophetic building example, a ceiling-mounted tile having an active area of about 0.36 m2 may face downward toward room surfaces and occupants. Using an in-band irradiance of about 184 W/m2 at about 300 K and an assumed overall conversion efficiency of about 2 percent, the output of one such tile may be about 1.3 W. A ceiling area of about 50 m2 using a plurality of such tiles may provide about 180 W under the stated assumptions, and may be connected to lighting, sensors, wireless access points, building automation loads, storage, or a DC aggregation bus.

In a dual-mode radiative-cooling and energy-harvesting embodiment, a panel may include a first surface configured to emit thermal radiation through an atmospheric window for cooling and a second surface including the chi-grid rectenna tile configured to harvest thermal radiation from an interior or lower-facing region. The radiative-cooling surface may include a selective emitter having high emissivity in a mid-infrared atmospheric window and lower absorption in a solar band. The energy-harvesting surface may include the phi-spiral/MIM rectenna architecture described herein. This dual-mode embodiment is a useful extension and continuation-worthy system embodiment, but it should not be treated as required for the broadest rectenna tile.

In a calculated or prophetic dual-mode example, a roof-mounted or envelope-mounted panel may include a top surface configured as a selective emitter having high emissivity in an 8 micrometer to 14 micrometer atmospheric window and low absorption in a solar band. The top surface may provide radiative-cooling heat rejection on the order of about 100 W/m2 under stated sky and environmental conditions, while a bottom or interior-facing chi-grid rectenna surface may harvest incident building thermal radiation, for example about 50 W/m2 of incident thermal power under stated assumptions. The combined thermal-management benefit may be expressed as an equivalent heat-management value under stated conditions rather than as a required electrical output of every embodiment.

In a fabrication example, a substrate is prepared and a ground plane is deposited on the substrate. A dielectric spacer is formed over the ground plane to a thickness selected for directional response at a target wavelength. An antenna metal layer is deposited and patterned to define phi-spiral antennas in a chi-grid arrangement. At or near each feedpoint, a tunnel barrier is formed by controlled oxidation, atomic layer deposition, sputtering, evaporation, or another thin-film process. A top electrode is formed over the tunnel barrier to define a MIM tunnel diode. DC busbars are patterned to connect diode outputs into series strings, parallel groups, or series-parallel networks. A passivation layer is deposited over at least a portion of the tile. Electrical contacts, output terminals, edge connectors, or conditioning circuitry may then be formed, and the tile may be tested for continuity, diode I-V behavior, spectral response, and DC output.

In another fabrication embodiment, a roll-to-roll process is used. A flexible web may pass through stations that imprint or pattern the phi-spiral antenna geometry, deposit or form a ground plane and spacer, deposit antenna metal, form the MIM barrier, define top electrodes, route DC busbars, apply passivation, perform optical or electrical metrology, and separate or package the completed tile. Roll-to-roll fabrication may support large-area manufacture, but it is optional. The core invention may also be fabricated using wafer-scale, panel-scale, batch lithography, nanoimprint, printing, laser writing, or other manufacturing processes.

In one roll-to-roll implementation, an imprint station may transfer the phi-spiral antenna pattern and ground-plane spacer topography, a coating station may deposit antenna metal and form a controlled-oxidation tunnel barrier, a lithography or maskless patterning station may define top electrodes and DC busbar routing, an integration station may deposit passivation and optional power-conditioning circuitry, and a metrology station may verify antenna response, impedance matching, continuity, and electrical output. In a calculated or prophetic production example, a web speed of about 2 m/min and a web width of about 300 mm may correspond to a production rate of about 0.6 m2 /min or about 36 m2/hour, with a target cost below about $50/m2 under stated materials, yield, and amortization assumptions.

In a validation process, the antenna response of a unit cell or tile may be measured or simulated over a target mid-infrared band. The impedance of the phi-spiral antenna may be compared to the impedance of the MIM tunnel diode. The diode may be characterized by measuring an I-V curve, identifying asymmetry, determining responsivity, and measuring junction resistance. A calibrated infrared source may illuminate the tile at a known intensity, wavelength band, angle, distance, and temperature. The resulting DC voltage, current, power, ripple, and load behavior may be measured. A validation report may identify whether each value is measured, simulated, calculated, specified, or prophetic.

In some embodiments, a fabrication design file is generated for the tile. The fabrication design file may define phi-spiral antenna geometry, unit-cell pitch, MIM diode placement, layer stack, material selections, busbar routing, series-parallel topology, output contacts, and tile dimensions. The fabrication design file may be used to pattern physical structures or validate a proposed tile layout. Where software or computer-readable media are described, the software should be tied to generation, verification, or manufacture of a physical rectenna tile or unit-cell layout rather than to an abstract calculation alone.

The disclosed tile can be scaled by changing the number of unit cells, tile area, series-string length, parallel-string count, substrate type, target spectral band, diode material, and output conditioning. A small tile may be used to power intermittent sensors. A larger panel may be used to supplement building electronics. A high-temperature variant may be adapted to industrial heat sources. A flexible variant may be adapted to wearable or curved surfaces. These scale changes do not alter the basic rectenna mechanism of receiving mid-infrared thermal radiation with phi-spiral antennas, rectifying the antenna-induced signal with MIM tunnel diodes, and collecting DC output across a chi-grid array.

The disclosure therefore provides multiple fallback layers. At the broadest level, the tile includes phi-spiral antenna/MIM rectenna unit cells arranged in a chi-grid array and connected to provide DC output from mid-infrared thermal radiation. In narrower embodiments, the tile is configured for the 8 micrometer to 14 micrometer atmospheric window. In still narrower embodiments, the unit-cell pitch is based on lambda_target * phi, the ground plane is spaced at about lambda_target/(4n), the antenna follows r(theta)=r0 * exp(theta / (phi * 2 pi)), and the MIM diode uses a selected barrier thickness and material system. In additional fallback embodiments, the array includes eight-cell mode-balanced supercells, a phi-ratio converter, roll-to-roll fabrication, building integration, wearable integration, industrial integration, or dual radiative-cooling functionality.

The invention should be understood as including equivalents and variations that preserve the disclosed rectenna function. For example, the antenna may include fabrication-toleranced phi-spiral arms, the MIM diode may be positioned at or near the feedpoint, the pitch may be within a tolerance of the target phi-based pitch, the ground-plane spacing may be approximately quarter-wave, and the collection network may use different series-parallel arrangements. Such variations may be selected to accommodate fabrication constraints, source temperature, substrate material, load requirements, or deployment geometry while preserving the core mid-infrared rectenna tile architecture.

Formal verification may be used to support mathematical design relationships of the disclosed rectenna tile. In one embodiment, a Lean 4 module identified as IndisputableMonolith. Applied. ChiGridRectenna defines or verifies relationships concerning wienPeakWavelength, AtmosphericWindow, PhiSpiralAntenna, ChiGridCell, RectennaEfficiency, Tile, thermalIrradiance, and atmosphericWindowFraction. Formal results may include wien_peak_in_midIR, wien_in_window, thermal_300K_approx, cellDensity_pos, overall_pos, overall_le_one, tilePower_pos, and chi_grid_rectenna_viable. An eight-cell supercell embodiment may be supported by a formal result such as sum_8_phases_eq_zero in an eight-tick module. Phi-related identities may include phi_sq_eq_phi_add_one, phi_pos, one_lt_phi, and, where supported, phi_ratio_optimal. These formal verification results support mathematical consistency of selected design rules, such as wavelength placement, atmospheric-window targeting, positive cell density, bounded efficiency factors, positive tile power under stated assumptions, phi relationships, and optional supercell mode balancing. They do not by themselves prove physical conversion efficiency, manufacturing yield, cost, durability, or commercial performance unless those properties are separately measured, simulated, calculated, specified, or prophetically described.

1. A directional mid-infrared rectenna energy-harvesting tile comprising:
an array of chi-grid unit cells disposed on a substrate;
a plurality of phi-spiral antennas included in the chi-grid unit cells, each phi-spiral antenna being configured to receive incident mid-infrared thermal radiation and to produce an antenna-induced signal at a feedpoint;
a plurality of metal-insulator-metal tunnel diodes electrically coupled at or near respective feedpoints of the phi-spiral antennas and configured to rectify the antenna-induced signals by quantum tunneling; and
a DC collection network electrically coupled to the plurality of metal-insulator-metal tunnel diodes and configured to collect rectified outputs from the chi-grid unit cells and provide DC electrical output derived from the incident mid-infrared thermal radiation.

2. The tile of claim 1, wherein the phi-spiral antennas are configured for broadband reception within an atmospheric mid-infrared window from about 8 micrometers to about 14 micrometers.

3. The tile of claim 1, wherein each phi-spiral antenna has a geometry defined at least in part by r(theta)=r0 * exp(theta/(phi * 2 pi)), where phi=(1+sqrt(5))/2, or comprises a fabrication-toleranced golden-ratio spiral variant.

4. The tile of claim 1, wherein each phi-spiral antenna has an inner radius based on lambda_min/(2 pi) and an outer radius based on lambda_max/(2 pi), where lambda_min and lambda_max define a target spectral band.

5. The tile of claim 1, wherein the chi-grid unit cells are arranged at a pitch P that is equal to, approximately equal to, or within a fabrication tolerance of lambda_target * phi, where lambda_target is a target thermal wavelength and phi=(1+sqrt(5))/2.

6. The tile of claim 5, wherein lambda_target is determined from a thermal source temperature T according to lambda_peak=2898/T, where lambda_peak is expressed in micrometers and T is expressed in kelvin.

7. The tile of claim 1, further comprising a ground plane and a dielectric spacer disposed between the ground plane and an antenna metal layer including the phi-spiral antennas, wherein the ground plane is spaced from the antenna metal layer by a distance selected to provide directional mid-infrared reception.

8. The tile of claim 7, wherein the ground plane is spaced from the antenna metal layer by approximately lambda_target/(4n), where n is a refractive index of the dielectric spacer.

9. The tile of claim 1, wherein each metal-insulator-metal tunnel diode comprises a bottom electrode, a tunnel barrier, and a top electrode, the tunnel barrier having a thickness from about 1 nm to about 5 nm and a barrier height from about 0.05 eV to about 0.5 eV.

10. The tile of claim 9, wherein the metal-insulator-metal tunnel diode comprises an asymmetric material stack configured to provide rectifying current-voltage behavior, the asymmetric material stack including at least one of Ni/NiO/Au, Al/Al2O3/Pt, Cr/Cr2O3/Au, Ti/TiO2, or a HfO2-based metal-insulator-metal stack.

11. The tile of claim 1, wherein the DC collection network comprises passive DC busbars, series strings, parallel string groups, or a series-parallel topology configured to aggregate voltage and current from the rectified outputs.

12. The tile of claim 1, further comprising a power-conditioning circuit electrically coupled to the DC collection network, the power-conditioning circuit comprising at least one of a boost converter, switched-capacitor converter, phi-ratio switched-capacitor converter, regulator, storage capacitor, bypass capacitor, protection circuit, or load-matching circuit.

13. The tile of claim 1, wherein the chi-grid unit cells are arranged in repeating supercells having a feed ordering configured to provide mode-balanced electrical collection.

14. The tile of claim 13, wherein each repeating supercell includes eight unit cells.

15. The tile of claim 1, wherein the substrate comprises a flexible substrate selected from PET, PEN, or polyimide, or a rigid substrate selected from glass, ceramic, silicon, or a high-temperature support material.

16. The tile of claim 1, wherein the tile is configured for an ambient thermal source having a temperature from about 290 K to about 310 K, or for an industrial thermal source having a temperature from about 400 K to about 800 K.

17. A method of harvesting energy from mid-infrared thermal radiation, the method comprising:
exposing a directional mid-infrared rectenna energy-harvesting tile to a thermal radiation source;
receiving incident mid-infrared thermal radiation with phi-spiral antennas arranged in chi-grid unit cells of the tile;
producing antenna-induced signals at feedpoints of the phi-spiral antennas;
rectifying the antenna-induced signals using metal-insulator-metal tunnel diodes electrically coupled at or near the feedpoints, thereby generating rectified outputs derived from the incident mid-infrared thermal radiation; and
collecting the rectified outputs through a DC collection network to provide DC electrical output.

18. The method of claim 17, further comprising determining a target wavelength from a source temperature of the thermal radiation source, selecting a unit-cell pitch based on the target wavelength and phi, and selecting inner and outer radii of the phi-spiral antennas based on minimum and maximum wavelengths of a target spectral band.

19. The method of claim 17, further comprising validating the tile by performing at least one of a spectral response measurement, diode current-voltage measurement, diode responsivity measurement, DC output measurement, power-density calculation, array-continuity test, or output-under-load test, and generating a validation report identifying whether at least one performance value is measured, simulated, calculated, specified, or prophetic.

20. A method of fabricating a directional mid-infrared rectenna energy-harvesting tile, the method comprising:
preparing a substrate;
forming a ground plane over the substrate;
forming a dielectric spacer over the ground plane;
patterning phi-spiral antennas in a chi-grid array over the dielectric spacer;
forming metal-insulator-metal tunnel diode regions electrically coupled at or near feedpoints of the phi-spiral antennas;
forming top electrodes for the metal-insulator-metal tunnel diode regions;
forming DC busbars electrically coupled to the metal-insulator-metal tunnel diode regions; and
forming a passivation layer over at least a portion of the tile.
